(19) United States
(12) Patent Application Publication
(10) Pub. No.: US 2006/0125014 A1
(43) Pub. Date: Jun. 15, 2006

(54) Diode with low junction capacitance

(76) Inventors: Nui Chong, San Jose, CA (US); Chun Jiang, San Jose, CA (US); Loc Nguyen, San Jose, CA (US)

Correspondence Address: LATTICE SEMICONDUCTOR CORPORATION, 5555 NE MOORE COURT, HILLSBORO, OR, 97124-6421, US

(21) Appl. No.: 11/012,466

(22) Filed: Dec. 14, 2004

(51) Int. Cl. H01L 23/62

(52) U.S. Cl. 257/355

(57) ABSTRACT

A diode is comprised of a doped region formed with a first dopant of a first conductivity type. In addition, the diode further comprises a substrate doped with a second dopant of a second conductivity type opposite of the first conductivity type. The lightly doped substrate, instead of a well, abuts the doped region for minimizing a junction capacitance of the diode. Such a diode is especially advantageous for ESD (electro-static discharge) protection of high speed integrated circuits.

### TECHNICAL FIELD

The present invention relates generally to integrated circuits, and more particularly, to diodes with low junction capacitance, especially amenable for ESD (electro-static discharge) protection of high-speed integrated circuits.

### BACKGROUND

FIG. 1 shows a block diagram of a system 100 for protection of an IC (integrated circuit) 102 from ESD (electro-static discharge) damage. A first diode 104 and a second diode 106 are coupled in parallel between a node 108 of the IC 102 to be protected and a power supply node (such as a ground node) 110.

ESD (electro-static discharge) transfers excessive charge to the node 108 potentially causing damage to the IC 102. The P-type region of the first diode 104 is coupled to the protected node 108, and the N-type region of the first diode 104 is coupled to the ground node 110, for dissipating positive ESD charge build-up at the protected node 108. The N-type region of the second diode 106 is coupled to the protected node 108, and the P-type region of the second diode 106 is coupled to the ground node 110, for dissipating negative ESD charge build-up at the protected node 108.

FIG. 2 shows a cross-sectional view of an N+ diode 120 which may be used as one of the diodes 104 and 106. A substrate 122 is typically doped with a dopant of P-type conductivity having a dopant concentration of about 1×10¹⁵/cm³. For forming the N+ diode 120, a P-well 124 is formed within the substrate 122 and is doped with a dopant of P-type conductivity having a dopant concentration of about 1×10¹⁷/cm³ to 1×10¹⁸/cm³.

Thereafter, an N+ doped region 126 is formed within the P-well 124 and is doped with a dopant of N-type conductivity having a dopant concentration of about 1×10²⁰/cm³. In addition, a P+ contact region 128 is formed within the P-well 124 for providing low resistance contact to the P-well 124. The P+ contact region 128 is doped with a dopant of P-type conductivity having a dopant concentration of about 1×10²⁰/cm³.

A first STI (shallow trench isolation) structure 130 is formed between the N+ doped region 126 and the P+ contact region 128 to separate such regions 126 and 128. A second STI (shallow trench isolation) structure 132 is formed to surround the P+ contact region 128 to electrically isolate the N+ diode 120.

Similarly, FIG. 3 shows a cross-sectional view of a P+ diode 140 which may be used as one of the diodes 104 and 106. For forming the P+ diode 140, an N-well 144 is formed within the substrate 122 and is doped with a dopant of N-type conductivity having a dopant concentration of about 1×10 ¹⁷/cm³ to 1×10¹⁸/cm³.

Thereafter, a P+ doped region 146 is formed within the N-well 144 and is doped with a dopant of P-type conductivity having a dopant concentration of about 1×10²⁰/cm³. In addition, an N+ contact region 148 is formed within the N-well 144 for providing low resistance contact to the N-well 144. The N+ contact region 148 is doped with a dopant of N-type conductivity having a dopant concentration of about 1×10²⁰/cm³.

A first STI (shallow trench isolation) structure 150 is formed between the P+ doped region 146 and the N+ contact region 148 to separate such regions 146 and 148. A second STI (shallow trench isolation) structure 152 is formed to surround the N+ contact region 148 to electrically isolate the P+ diode 140.

In such prior art diodes 120 and 140, the N+ diode 120 is formed with the N+ doped region 126 abutting the P-well 124, and the P+ diode 140 is formed with the P+ doped region 146 abutting the N-well 144. Generally, P-wells and N-wells are formed through-out the substrate 122 to form structures of the integrated circuit 102.

The junction capacitance of such prior art diodes 120 and 140 may not be lowered beyond a limit. However, when the protected node 108 is for the integrated circuit 102 operating at high speed, the junction capacitance of such prior art diodes 120 and 140 limits the speed performance of the integrated circuit 102. For example, the protected node 108 may be an I/O (input/output) node of the integrated circuit 102 that is a SERDES (serializer/deserializer) chip operating at 6 GHz to 10 GHz. In that case, the capacitance budget at the protected node 108 is less than 100 fF (femto-Ferrads). However, the prior art diodes 120 and 140 may not be formed with such low capacitance, resulting in distortion of a high frequency signal at the protected node 108.

### SUMMARY

Accordingly, in a general aspect of the present invention, a diode is formed with lower junction capacitance which is especially advantageous for ESD (electro-static discharge) protection of high speed integrated circuits.

In an aspect of the present invention, such a diode is comprised of a doped region formed with a first dopant of a first conductivity type. In addition, the diode further comprises a substrate doped with a second dopant of a second conductivity type opposite of the first conductivity type. The lightly doped substrate, instead of a well, abuts the doped region for minimizing junction capacitance of the diode.

These and other features and advantages of the present invention will be better understood by considering the following detailed description of the invention which is presented with the attached drawings.

### BRIEF DESCRIPTION OF THE DRAWINGS

FIG. 1 shows a block diagram of a system for protection of an IC (integrated circuit) from ESD (electro-static discharge) damage, according to the prior art;

FIG. 2 shows a cross-sectional view of an N+ diode formed with a P-well, according to the prior art;

FIG. 3 shows a cross-sectional view of a P+ diode formed with an N-well, according to the prior art;

FIG. 4 shows a block diagram of a system for protection of an IC (integrated circuit) from ESD (electro-static discharge) damage, according to an embodiment of the present invention;

FIGS. 5, 6, 7, 8, 9, and 10 show cross-sectional views of an N+ diode formed with a substrate abutting a diode junction, according to embodiments of the present invention;

FIGS. 11 and 12 show cross-sectional views of a P+ diode formed with a substrate abutting a diode junction, according to embodiments of the present invention;

FIG. 13 shows a table of performance characteristics for the N+ of FIGS. 2, 5, 6, and 14, according to embodiments of the present invention;

FIG. 14 shows the N+ diode similar to FIG. 5 but with increased width of a STI (shallow trench isolation) structure, according to an embodiment of the present invention;

FIG. 15 shows a top view of the N+ diode of FIG. 5, according to an embodiment of the present invention;

FIGS. 16, 17, and 18 show cross-sectional views including a depletion region of the N+ poly-bounded diode of FIG. 10 for various widths of a poly gate structure, according to embodiments of the present invention; and

FIGS. 19, 20, and 21 show cross-sectional views including a depletion region of the N+ STI-bounded diode of FIG. 5 for various widths of the STI structure, according to embodiments of the present invention.

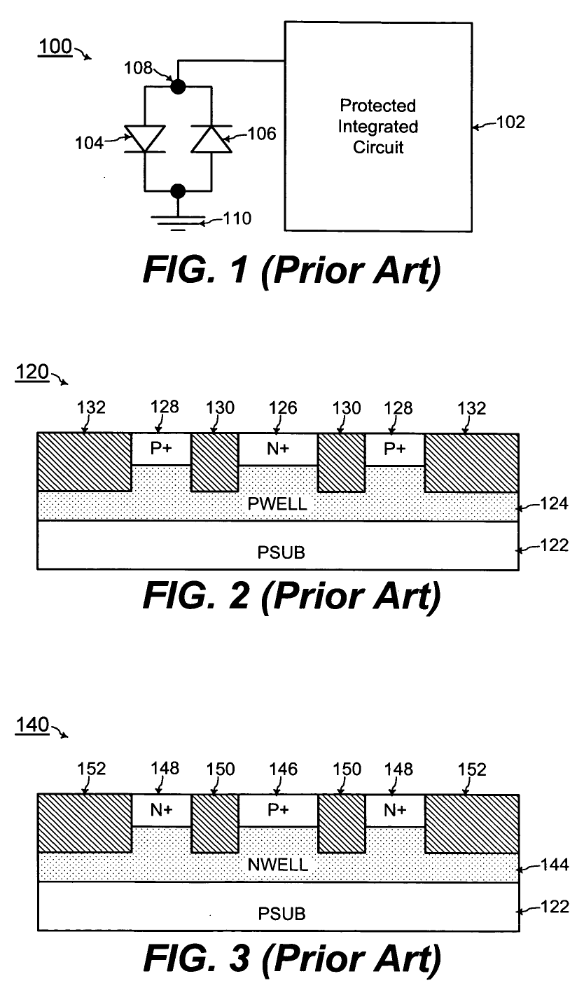

The figures referred to herein are drawn for clarity of illustration and are not necessarily drawn to scale. Elements having the same reference number in FIGS. 1, 2, 3, 4, 5, 6, 7, 8, 9, 10, 11, 12, 13, 14, 15, 16, 17, 18, 19, 20, and 21 refer to elements having similar structure and function.

### DETAILED DESCRIPTION

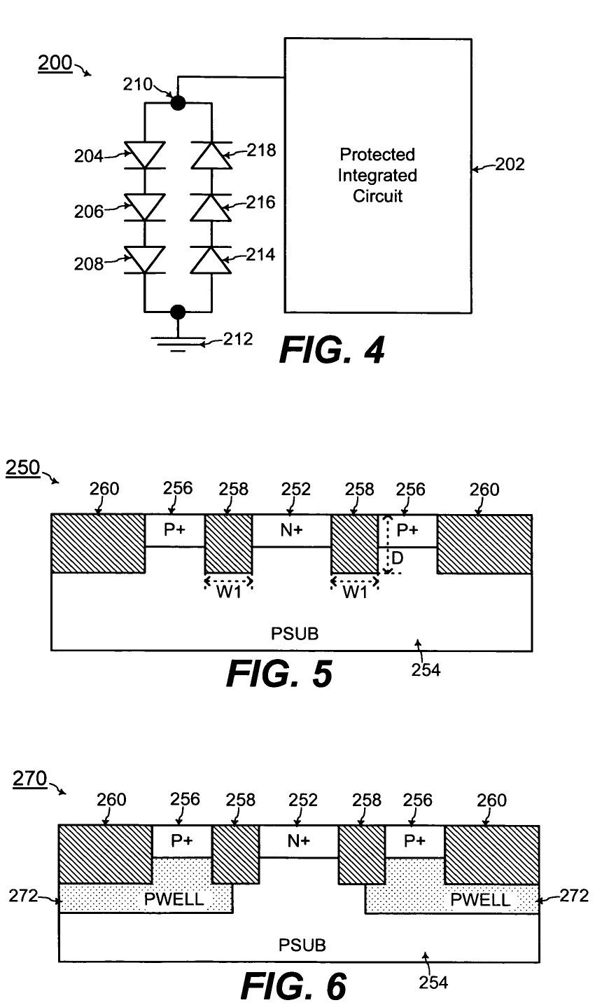

FIG. 4 shows a system 200 for protection of an IC (integrated circuit) 202 from ESD (electro-static discharge) damage, according to an embodiment of the present invention. A first cascade of diodes 204, 206, and 208 are coupled between a protected node 210 of the IC 202 and a ground node 212. The diodes 204, 206, and 208 are coupled in series with the P-type region of the diode 204 being coupled to the protected node 210 and the N-type region of the diode 204 being coupled to the ground node 212.

In this manner, the first cascade of diodes 204, 206, and 208 dissipates positive ESD charge build-up at the protected node 210. The plurality of diodes 204, 206, and 208 turn on when the voltage at the protected node 210 reaches the sum of the turn-on voltages of the diodes 204, 206, and 208, such as 2 Volts to 3 Volts for example.

Similarly, a second cascade of diodes 214, 216, and 218 are coupled between the ground node 212 and the protected node 210. The diodes 214, 216, and 218 are coupled in series with the P-type region of the diode 214 being coupled to the ground node 212 and the N-type region of the diode 218 being coupled to the protected node 210.

In this manner, the second cascade of diodes 214, 216, and 218 dissipates negative ESD charge build-up at the protected node 210. The plurality of diodes 214, 216, and 218 turn on when the voltage at the protected node 210 reaches the negative of the sum of the turn-on voltages of the diodes 214, 216, and 218, such as −2 Volts to −3 Volts for example.

In an example embodiment of the present invention, the protected node 210 is coupled to an I/O pad of the IC 202 that is a SERDES (serializer/deserializer) chip operating at high speed such as 6-10 GHz (giga-Hertz) for example. However, the system 200 may also be used for protection of other types of integrated circuits from ESD (electro-static discharge) damage.

FIG. 5 shows a cross-sectional view of an N+ diode 250 which may be used for any of the diodes 204, 206, 208, 214, 216, and 218 of FIG. 4. Referring to FIG. 5, an N+ doped region 252 is formed within a P-type substrate 254. The N+ doped region 252 is formed from implantation of an N-type dopant into the P-type substrate 254 for example. The P-type substrate 254 is doped with a P-type dopant having a dopant concentration of 1×10¹⁵/cm³ to 1×10 ¹⁶/cm³, in one embodiment of the present invention. The N+ doped region 252 is doped with an N-type dopant having a dopant concentration of about 1×10²⁰/cm³, in one embodiment of the present invention.

The dopant concentration of the N+ doped region 252 is at least 10³ times the dopant concentration of the P-type substrate 254, in one embodiment of the present invention. The N+ diode 250 is formed by the junction between the N+ doped region 252 and the P-type substrate 254. The junction capacitance of the diode 250 is inversely proportional to a depletion width formed at the junction between the N+ doped region 252 and the P-type substrate 254.

If the dopant concentration of the P-type substrate 254 is about 1×10¹⁵/cm³, the depletion width within the P-type substrate 254 is about 1 μm in the diode 250 of the present invention. In contrast, when the N+ doped region 126 abuts the P-well 124 having a dopant concentration of about 1×10¹⁷/cm³ to 1×10¹⁸/cm³, the depletion width within the P-well 124 is about 0.1 μm in the diode 120 of the prior art. Thus, the junction capacitance in the diode 250 of the present invention is decreased by an order of magnitude (i.e., by a factor of 10) from the diode 120 of the prior art.

Further referring to FIG. 5, the N+ diode 250 also includes a P+ contact region 256 doped with a P-type dopant having a dopant concentration of about 1×10²⁰/cm³. Such a P+ contact region 256 provides low-resistance contact to the P-type substrate 254. A first shallow trench isolation structure 258 is formed to separate the N+ doped region 252 from the P+ contact region 256. In addition, a second shallow trench isolation structure 260 is formed to surround the P+ contact region 256 to electrically isolate the N+ diode 250. Processes for forming STI (shallow trench isolation) structures in general are individually known to one of ordinary skill in the art of integrated circuit fabrication.

FIG. 6 illustrates a cross-sectional view of an N+ diode 270 according to another embodiment of the present invention. Elements having the same reference number in FIGS. 5 and 6 refer to elements having similar structure and function. Thus, the N+ diode 270 of FIG. 6 is similar to the N+ diode 250 of FIG. 5. However, the N+ diode 270 of FIG. 6 further includes a P-type contact well 272 formed to contain the P+ contact region 256 within the substrate 254. The P-type contact well 272 is doped with a P-type dopant having a concentration of about 1×10¹⁷/cm³ to 1×10 ¹⁸/cm³. Such a P-type contact well 272 further lowers the resistance for contact to the P-type substrate 254.

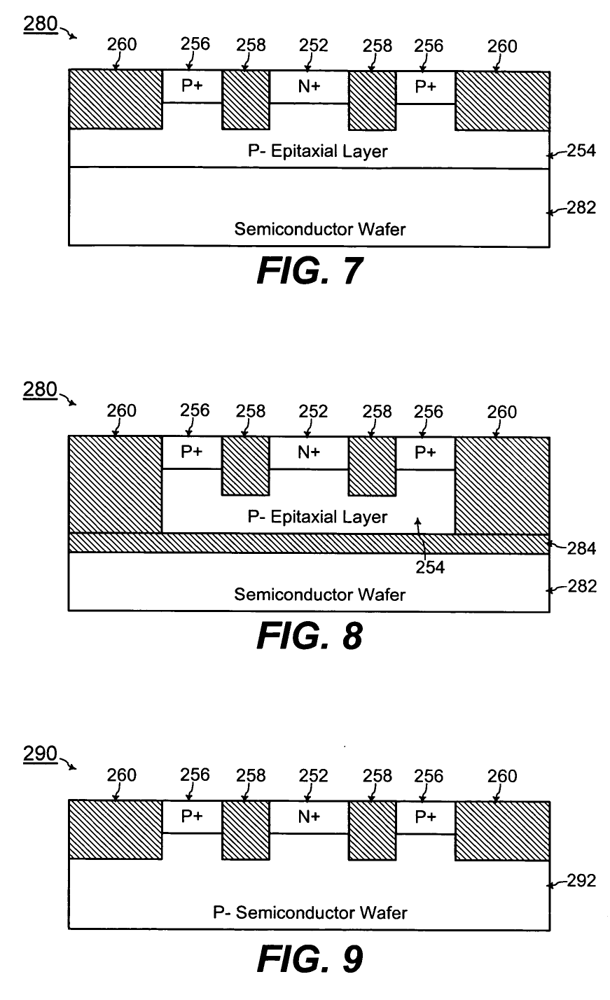

FIG. 7 illustrates a cross-sectional view of an N+ diode 280 according to another embodiment of the present invention. Elements having the same reference number in FIGS. 5 and 7 refer to elements having similar structure and function. Thus, the N+ diode 280 of FIG. 7 is similar to the N+ diode 250 of FIG. 5. The P-type substrate 254 in the N+ diode 280 of FIG. 7 is formed with a P-type epitaxial layer of semiconductor material deposited onto a semiconductor wafer 282. The semiconductor wafer 282 is a silicon wafer in an example embodiment of the present invention.

Processes for deposition of the epitaxial layer 254 in FIG. 7 individually are known to one of ordinary skill in the art of integrated circuit fabrication. Such an epitaxial layer 254 is formed with a P-type dopant doping the epitaxial layer with a dopant concentration of about 1×10¹⁵/cm³ to about 1×10¹⁶/cm³. The epitaxial layer 254 is formed for the P-type substrate 254 abutting the N+ doped region 252 when the doping of the semiconductor wafer 282 is not desirable for abutting the N+ doped region 252. For example, the semiconductor wafer 282 may have a P-type dopant concentration that is higher than 1×10¹⁶/cm³, for example.

Referring to FIG. 8, an insulating layer 284 may further be formed between the epitaxial layer 254 and the semiconductor wafer 282 for electrically isolating the P-type epitaxial layer 254. Such an isolated P-type region 254 of the diode 280 is especially amenable for cascading a series of such diodes 280. Elements having the same reference number in FIGS. 7 and 8 refer to elements having similar structure and function.

FIG. 9 illustrates a cross-sectional view of an N+ diode 290 according to another embodiment of the present invention. Elements having the same reference number in FIGS. 5 and 9 refer to elements having similar structure and function. Thus, the N+ diode 290 of FIG. 9 is similar to the N+ diode 250 of FIG. 5. The P-type substrate 254 in the N+ diode 290 of FIG. 7 is formed with a semiconductor wafer 292 that is lightly doped with a P-type dopant having a dopant concentration of about 1×10¹⁵/cm³ to about 1×10¹⁶/cm³. The semiconductor wafer 292 is a silicon wafer in an example embodiment of the present invention.

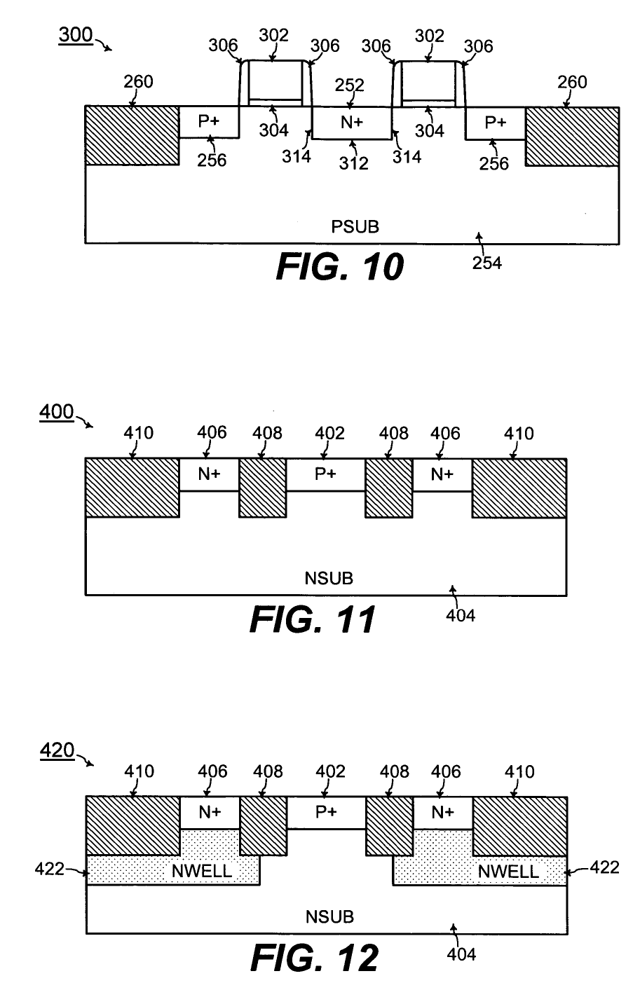

FIG. 10 illustrates a cross-sectional view of an N+ diode 300 according to another embodiment of the present invention. Elements having the same reference number in FIGS. 5 and 10 refer to elements having similar structure and function. However the N+ diode 300 of FIG. 10 does not include the first STI structure 258 for separating the N+ region 252 and the P+ contact region 256.

Rather, the N+ diode 300 of FIG. 10 includes a gate structure 302 disposed on a region of the P-type substrate 254 between the N+ region 252 and the P+ contact region 256. A dielectric structure 304 is disposed below the gate structure 302 on the P-type substrate 254. Spacers 306 are disposed on the sidewalls of the gate structure 302 and the dielectric structure 304.

Such elements 302, 304, and 306 are formed simultaneously during formation of similar structures for field effect transistors in the integrated circuit 202 at other portions of the P-type substrate 254, in one embodiment of the present invention. Thus, such elements 302, 304, and 306 are formed before the implantation process for forming the N+ doped region 252 and the P+ contact region 256. The gate structure 302 is comprised of polysilicon in one embodiment of the present invention. In that case, the N+ diode 300 is also referred to as a poly-bounded diode.

With the poly-bounded diode 300, the N+ doped region has multiple surfaces including a bottom surface 312 and side surfaces 314 abutting the P-type substrate 254 for increased junction area. In contrast, the N+ diode 250 of FIG. 5 just has the bottom surface of the N+ diode 252 abutting the P-type substrate 254. Such increased junction area with the poly-bounded diode 300 of FIG. 10 advantageously results in higher current conduction and thermal conduction.

FIG. 11 illustrates a cross-sectional view of a P+ diode 400 which may be used for any of the diodes 204, 206, 208, 214, 216, and 218 of FIG. 4, according to another embodiment of the present invention. Referring to FIG. 11, a P+ doped region 402 is formed within an N-type substrate 404. The P+ doped region 402 is formed from implantation of a P-type dopant into the N-type substrate 404 for example. The N-type substrate 404 is doped with an N-type dopant having a dopant concentration of 1×10¹⁵/cm³ to 1×10¹⁶/cm³, in one embodiment of the present invention. The P+ doped region 402 is doped with a P-type dopant having a dopant concentration of about 1×10²⁰/cm³, in one embodiment of the present invention.

The P+ diode 400 is formed by the junction between the P+ doped region 402 and the N-type substrate 404. Similar to the N+ diode 250 of FIG. 5, the dopant concentration of the P+ doped region 402 is at least 10³ times the dopant concentration of the N-type substrate 404 for decreased junction capacitance, in one embodiment of the present invention.

Further referring to FIG. 11, the P+ diode 400 also includes an N+ contact region 406 doped with an N-type dopant having a dopant concentration of about 1×10²⁰/cm³. Such an N+ contact region 406 provides low-resistance contact to the N-type substrate 404. A first shallow trench isolation structure 408 is formed to separate the P+ doped region 402 from the N+ contact region 406. In addition, a second shallow trench isolation structure 410 is formed to surround the N+ contact region 406 to electrically isolate the P+ diode 400.

FIG. 12 illustrates a cross-sectional view of a P+ diode 420 according to another embodiment of the present invention. Elements having the same reference number in FIGS. 11 and 12 refer to elements having similar structure and function. Thus, the P+ diode 420 of FIG. 12 is similar to the P+ diode 400 of FIG. 11. However, the P+ diode 420 of FIG. 12 further includes an N-type contact well 422 formed to contain the N+ contact region 406 within the substrate 404.

The N-type contact well 422 is doped with an N-type dopant having a concentration of about 1×10¹⁷/cm³ to 1×10¹⁸/cm³. Such an N-type contact well 422 further lowers the resistance for contact to the N-type substrate 404. In addition, the P+ diode of FIG. 11 may also be varied similar to FIGS. 7, 8, and 9 with formation of the N-type substrate 404 as an epitaxial layer on a semiconductor wafer or just as a semiconductor wafer.

In this manner, N+ or P+ diodes with reduced junction capacitance are formed with the N+ doped region 252 abutting a lightly doped P-type substrate 254 or with the P+ doped region 402 abutting a lightly doped N-type substrate 404. Such diodes with lower junction capacitance are especially advantageous for ESD (electro-static discharge) protection of the integrated circuit 202 operating at high speed.

Furthermore, the regions of the N+ or P+ diodes of FIGS. 5, 6, 7, 8, 9, 10, 11, and 12 are advantageously formed simultaneously for forming the integrated circuit 202 such that no additional fabrication steps are used. For example, the N+ or P+ diodes are fabricated using steps for fabrication of NMOSFETs (N-channel metal oxide semiconductor field effect transistors) and PMOSFETs (P-channel metal oxide semiconductor field effect transistors) of a CMOS process.

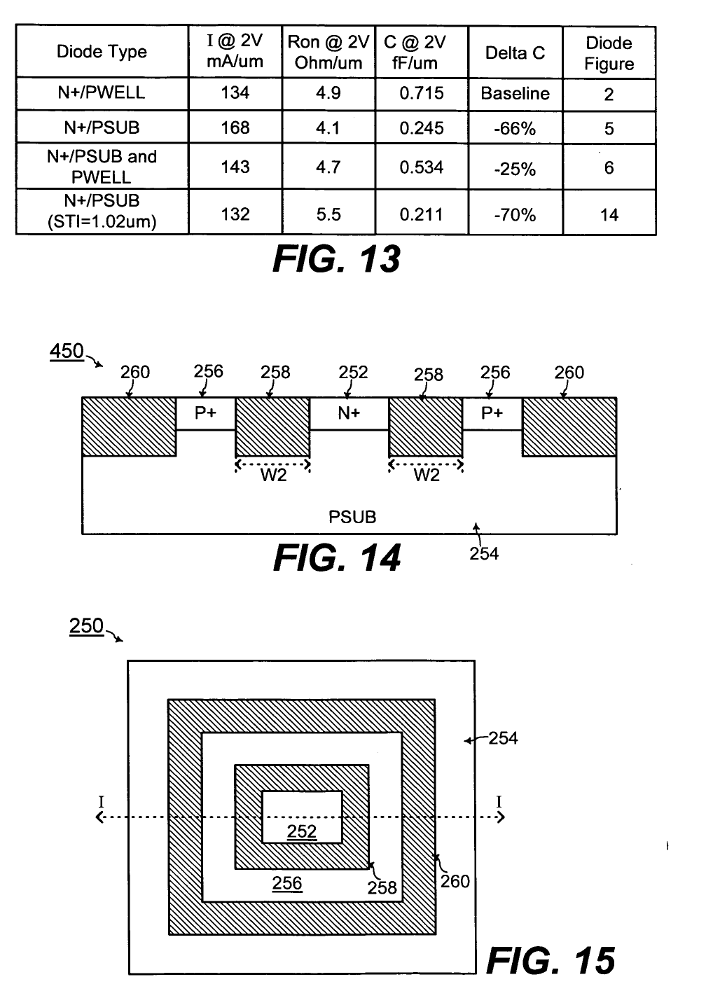

In addition, such diodes also have enhanced characteristics for ESD protection. FIG. 13 shows a table of performance characteristics for the N+ diodes of FIGS. 5, 6, and 14. Referring to FIG. 13, the N+ diode 120 of FIG. 2 has a current density of 134 mA/μm, a resistance of 4.9 Ohms/μm, and a capacitance of 0.715 fF/μm, when 2 Volts is applied across the junction formed by the N+ doped region 126 and the P-well 124.

Assume that the N+ diode 120 of FIG. 2 is the base-line case for such junction capacitance. Further referring to FIG. 13, the N+ diode 250 of FIG. 5 has a current density of 168 mA/μm, a resistance of 4.1 Ohms/μm, and a capacitance of 0.245 fF/μm, when 2 Volts is applied across the junction formed by the N+ doped region 252 and the P-type substrate 254 in FIG. 5.

Such junction capacitance of the N+ diode 250 of FIG. 5 is a 66% decrease from the baseline case of the N+ diode 120 of FIG. 2. In addition, for enhanced ESD (electro-static discharge) protection, a higher current density and lower resistance is desired for the diode. Higher current density results in faster dissipation of ESD charge build up, and lower resistance results in less power consumption. The N+ diode 250 of FIG. 5 has higher current density and lower resistance than the N+ diode 120 of FIG. 2.

Further referring to FIG. 13, the N+ diode 270 of FIG. 6 has a current density of 143 mA/μm, a resistance of 4.7 Ohms/μm, and a capacitance of 0.534 fF/μm, when 2 Volts is applied across the junction formed by the N+ doped region 252 and the P-type substrate 254 in FIG. 6. Such junction capacitance of the N+ diode 270 of FIG. 6 is a 25% decrease from the baseline case of the N+ diode 120 of FIG. 2. In addition, note that the N+ diode 270 of FIG. 6 has higher current density and lower resistance than the N+ diode 120 of FIG. 2.

FIG. 14 illustrates a cross-sectional view of an N+ diode 450 according to another embodiment of the present invention. Elements having the same reference number in FIGS. 5 and 14 refer to elements having similar structure and function. Thus, the N+ diode 450 of FIG. 14 is similar to the N+ diode 250 of FIG. 5. However, the first STI structure 258 of the N+ diode 450 of FIG. 14 has increased width W2 from the lower width W1 of the N+ diode 250 of FIG. 5. For example, the lower width W1 of the first STI structure 258 in FIG. 5 is 0.34 μm, and the increased width W2 of the first STI structure 258 in FIG. 14 is 1.02 μm, in one embodiment of the present invention.

Referring to FIGS. 13 and 14, such an N+ diode 450 of FIG. 14 has a current density of 132 mA/μm, a resistance of 5.5 Ohms/μm, and a capacitance of 0.211 fF/μm when 2 Volts is applied across the junction formed by the N+ doped region 252 and the P-type substrate 254 in FIG. 14. Such junction capacitance of the N+ diode 450 of FIG. 14 is a 70% decrease from the base-line case of the N+ diode 120 of FIG. 2. Thus, the increased width W2 of the first STI structure 258 in FIG. 14 results in lowered junction capacitance from the diode 250 in FIG. 5. However, such lowered junction capacitance is a trade-off with lowered current density and higher resistance in the diode 450 of FIG. 14.

FIG. 15 illustrates a top view of the N+ diode 250 of FIG. 5 with rectangular shapes for the elements 252, 256, 258, and 260. In that case, the cross-sectional view of FIG. 5 is across line I-I of FIG. 15. However, the present invention may be practiced with other shapes, such as circular shapes, for the elements 252, 256, 258, and 260.

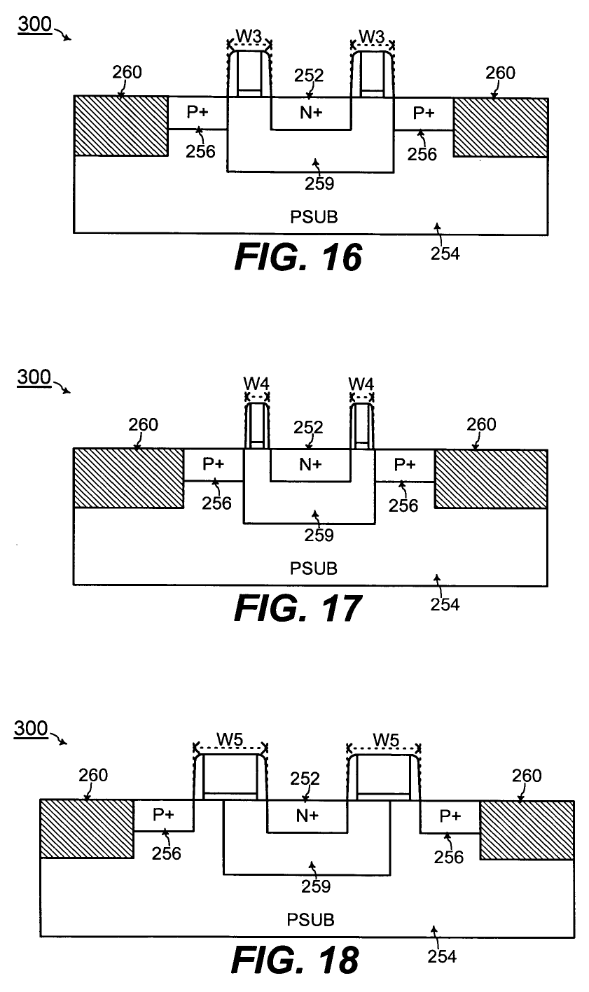

In addition, FIG. 16 shows a depletion region 259 formed in the lightly doped P-substrate 254 in the N+ poly-bounded diode 300 of FIG. 10. The width W3 of the gate structure 302 and the spacers 306 is small enough in FIG. 16 such that the depletion region 259 abuts the N+ doped region 252 and the P+ contact region 256 for minimizing the turn-on resistance of the diode 300.

FIG. 17 shows the depletion region with reduced depletion width between the N+ doped region 252 and the P+ contact region 256 with a reduced width W4 of the gate structure 302 and the spacers 306. Such reduced depletion width increases the capacitance of the diode 300. In this manner, the width of at least one of the gate structure 302 and the spacers 306 is adjusted for controlling the capacitance of the diode 300.

In FIG. 18, the width W5 of the gate structure 302 and the spacers 306 is large enough such that the depletion region 259 does not completely extend between the N+ doped region 252 and the P+ contact region 256. Thus, a portion of the lightly doped P-substrate 254 is disposed between the N+ doped region 252 and the P+ contact region 256 disadvantageously resulting in high turn-on resistance of the diode 300 of FIG. 18. In an embodiment of the present invention, the width of the gate structure 302 and the spacers 306 is designed to be small enough such that the depletion region 259 completely extends between the N+ doped region 252 and the P+ contact region 256 for minimizing turn-on resistance of the diode 300 as in FIGS. 16 and 17.

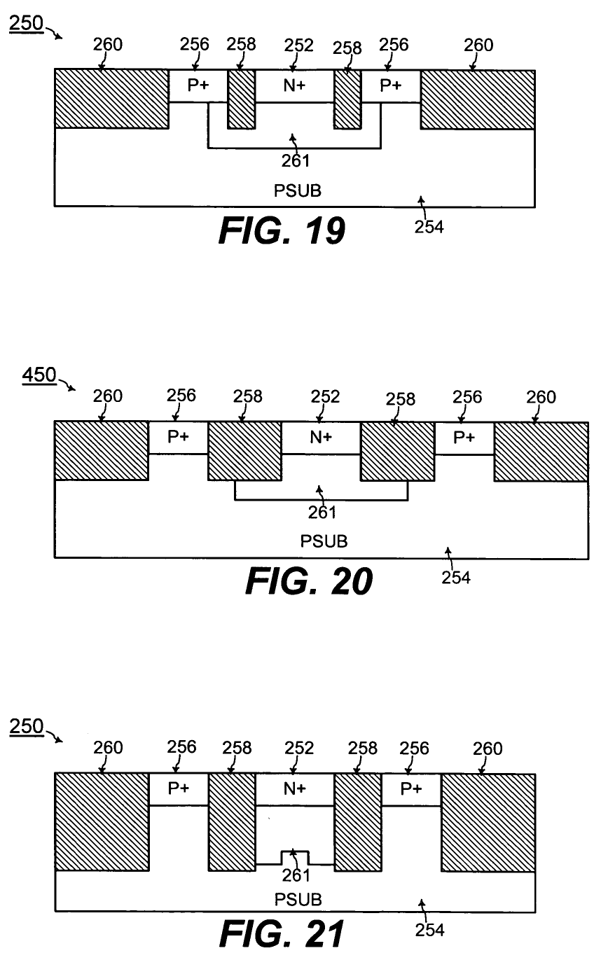

Similarly, FIG. 19 shows a depletion region 261 formed in the lightly doped P-substrate 254 in the N+ STI-bounded diode 250 of FIG. 5. The width W1 of the STI structure 258 is small enough in FIG. 19 such that the depletion region 261 abuts the N+ doped region 252 and the P+ contact region 256 for minimizing the turn-on resistance of the diode 250.

In addition, as described in reference to the table of FIG. 13, the width W1 of the STI structure 254 determines the capacitance of the diode 250. Thus, the width W1 of the STI structure 258 is adjusted for controlling the capacitance of the diode 300.

Referring to FIGS. 5 and 20, the width W1 of the STI structure 258 is large enough such that the depletion region 261 does not completely extend between the N+ doped region 252 and the P+ contact region 256 in FIG. 20. Thus, a portion of the lightly doped P-substrate 254 is disposed between the N+ doped region 252 and the P+ contact region 256 disadvantageously resulting in high turn-on resistance of the diode 250 of FIG. 20.

Similarly referring to FIGS. 5 and 21, the depth D of the STI structure 258 is large enough such that the depletion region 261 does not completely extend between the N+ doped region 252 and the P+ contact region 256 in FIG. 21. Thus, a portion of the lightly doped P-substrate 254 is disposed between the N+ doped region 252 and the P+ contact region 256 disadvantageously resulting in high turn-on resistance of the diode 250 of FIG. 21. In an embodiment of the present invention, the width W1 and the depth D of the STI structure 258 are designed to be small enough such that the depletion region 261 completely extends between the N+ doped region 252 and the P+ contact region 256 for minimizing turn-on resistance of the diode 250 as in FIG. 19.

The foregoing is by way of example only and is not intended to be limiting. For example, the present invention is described for use of the N+ or P+ diodes for ESD (electro-static discharge) protection. However, such N+ or P+ diodes with lower junction capacitance may be used for any other application. In addition, any materials or parameter values specified herein are by way of example only. Furthermore, any number or shape of elements as illustrated and described herein is by way of example only.

The present invention is limited only as defined in the following claims and equivalents thereof.

1. A diode comprising:
a doped region formed with a first dopant of a first conductivity type; and
a substrate doped with a second dopant of a second conductivity type opposite of the first conductivity type,
wherein the substrate, instead of a well, abuts the doped region for minimizing a junction capacitance of the diode.

2. The diode of claim 1, wherein a first dopant concentration of the doped region is at least 10³ times greater than a second dopant concentration of the substrate.

3. The diode of claim 1, wherein the substrate is an epitaxial layer formed on a semiconductor wafer.

4. The diode of claim 1, wherein the substrate is a semiconductor wafer.

5. The diode of claim 1, further comprising:
a contact region disposed within the substrate and formed with the second dopant having a dopant concentration higher than of the substrate.

6. The diode of claim 5, further comprising:
a contact well disposed below the contact region within the substrate and formed with the second dopant having a dopant concentration lower than of the contact region and higher than of the substrate.

7. The diode of claim 5, further comprising:
a STI (shallow trench isolation) structure disposed between the contact region and the doped region within the substrate.

8. The diode of claim 7, wherein a width of the STI structure determines the junction capacitance of the diode.

9. The diode of claim 5, further comprising:
a boundary structure disposed on a region of the substrate between the contact region and the doped region.

10. The diode of claim 9, wherein a width of the boundary structure determines the junction capacitance of the diode.

11. The diode of claim 1, wherein one of the doped region and the substrate is coupled to a node of an integrated circuit to be protected from ESD (electro-static discharge).

12. A diode comprising:
a doped region formed with a first dopant of a first conductivity type; and
a substrate abutting the doped region and doped with a second dopant of a second conductivity type opposite of the first conductivity type,
wherein a first dopant concentration of the doped region is at least 10³ times greater than a second dopant concentration of the substrate.

13. A system for ESD (electro-static discharge) protection of an integrated circuit fabricated within a substrate, the system comprising:
a first cascade of at least one diode coupled to a node of the integrated circuit for dissipating positive charge at the node from ESD; and
a second cascade of at least one diode coupled to the node of the integrated circuit for dissipating negative charge at the node from ESD;
wherein at least one diode of the first and second cascades comprises:
a doped region formed with a first dopant of a first conductivity type; and
the substrate doped with a second dopant of a second conductivity type opposite of the first conductivity type,
wherein the substrate, instead of a well, abuts the doped region for minimizing a junction capacitance of the diode.

14. The system of claim 13, wherein a first dopant concentration of the doped region is at least 10³ times greater than a second dopant concentration of the substrate.

15. The system of claim 13, wherein the substrate is an epitaxial layer formed on a semiconductor wafer.

16. The system of claim 13, wherein the substrate is a semiconductor wafer.

17. The system of claim 13, wherein the diode further comprises:
a contact region disposed within the substrate and formed with the second dopant having a dopant concentration higher than of the substrate.

18. The system of claim 17, wherein the diode further comprises:
a contact well disposed below the contact region within the substrate and formed with the second dopant having a dopant concentration lower than the of contact region and higher than of the substrate.

19. The system of claim 17, wherein the diode further comprises:
a STI (shallow trench isolation) structure disposed between the contact region and the doped region within the substrate.

20. The system of claim 17, wherein the diode further comprises:
a boundary structure disposed on a region of the substrate between the contact region and the doped region.
